(19) United States
(12) Patent Application Publication
(10) Pub. No.: US 2015/0170989 A1
(43) Pub. Date: Jun. 18, 2015

(54) THREE-DIMENSIONAL (3D) INTEGRATED HEAT SPREADER FOR MULTICHIP PACKAGES

(71) Applicants: Hemanth K. Dhavaleswarapu, Chandler, AZ (US); Roger D. Flynn, Tempe, AZ (US); Sanjoy K. Saha, Chandler, AZ (US)

(72) Inventors: Hemanth K. Dhavaleswarapu, Chandler, AZ (US); Roger D. Flynn, Tempe, AZ (US); Sanjoy K. Saha, Chandler, AZ (US)

(21) Appl. No.: 14/108,270

(22) Filed: Dec. 16, 2013

(51) Int. Cl. H01L 23/34; H01L 25/00

(52) U.S. Cl. CPC H01L 23/34; H01L 25/50; H01L 25/00

(57) ABSTRACT

Embodiments of the present disclosure describe thermal management solutions for multichip package assemblies and methods of fabricating multichip package assemblies utilizing the thermal management solutions. These embodiments include multi-level heat spreaders and alleviate issues caused by dimensional variability in die-packages utilized in multichip package assemblies. In one embodiment a package heat spreader is thermally coupled to a first die-package and die-package heat spreader. The die-package heat spreader is thermally coupled to a second die-package and provides a thermal pathway to conduct heat from the second die-package to the package heat spreader. Other embodiments may be described and/or claimed.

### FIELD

Embodiments of the present disclosure generally relate to the field of integrated circuits package assemblies, and more particularly, to heat spreading schemes for integrated circuit package assemblies as well as methods for fabricating package assemblies employing the heat spreading schemes.

### BACKGROUND

As package assemblies become more complicated and incorporate multiple dies in close proximity to one another removing heat from the various elements has become more challenging. The inability to remove heat from dies can result in overheating or require that components operate at less than their full capacity to prevent overheating. Heat removal is particularly challenging where the dimensions of dies may vary due to fabrication tolerances or other factors. Variability in die dimensions may result in relatively thick layers of thermal interface material (TIM) that are unable to adequately transfer heat away from the die. Variability in die dimensions may also necessitate TIM layers with substantial compressibility thus restricting the use of certain materials that may exhibit desirable heat transfer characteristics, but fail to meet the compressibility requirements.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIGS. 1A-C schematically illustrate cross-section side views of a package assembly showing variation in die-package dimensions.

FIGS. 2A-F schematically illustrate cross-section side views of a package assembly including various die-package heat spreaders, in accordance with some embodiments.

FIG. 3 schematically illustrates a flow diagram of a method of fabricating a package assembly, in accordance with some embodiments.

FIGS. 4A-C schematically illustrate cross-section side views of a heat spreader and package assembly including the heat spreader, in accordance with some embodiments.

FIG. 5 schematically illustrates a flow diagram of a method of fabricating a package assembly, in accordance with some embodiments.

FIGS. 6A-B schematically illustrate cross-section side views of package assemblies consistent with the method of FIG. 5, in accordance with some embodiments.

FIG. 7 schematically illustrates a cross-section side view of a package assembly including multiple die-package heat spreaders, in accordance with some embodiments.

FIG. 8 schematically illustrates a computing device that includes a package assembly as described herein, in accordance with some embodiments.

### DETAILED DESCRIPTION

Embodiments of the present disclosure describe thermal management solutions for multichip package assemblies and methods of fabricating multichip package assemblies utilizing the thermal management solutions. These embodiments include multi-level heat spreaders and alleviate issues caused by dimensional variability in die-packages utilized in multichip package assemblies. Additionally, heat spreaders according to some embodiments may have substantially flat upper surfaces. This may facilitate thermal and other testing of the package assemblies without requiring customized test fixtures.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “in embodiments,” or “in some embodiments,” which may each refer to one or more of the same or different embodiments. Furthermore, the terms “comprising,” “including,” “having,” and the like, as used with respect to embodiments of the present disclosure, are synonymous.

The term “coupled with” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group) and/or memory (shared, dedicated, or group) that execute one or more software or firmware programs, a combinational logic circuit, and/or other suitable components that provide the described functionality.

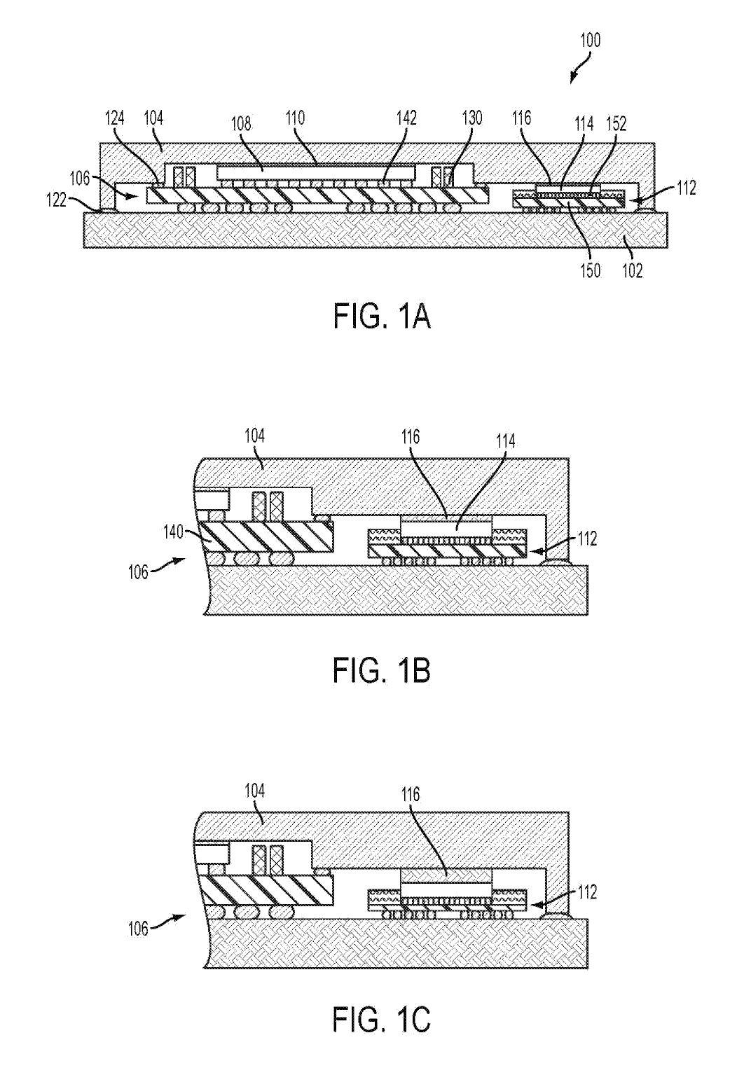

FIGS. 1A-C illustrate a package assembly 100 including one or more die-packages such as die-packages 106 and 112. The die-packages 106 and 112 may be connected to a package substrate 102 such as by a ball grid array (BGA) (not labeled). Die-package 106 may include one or more dies, such as die 108. The one or more dies, such as die 108, may be coupled to a die-package substrate 140 by die-package interconnects 142. Die-package interconnects 142 may be any suitable structures, including but not limited to a BGA, bumps, or posts. Die 108 may contain any passive or active elements. For instance, die 108 may include a processor or central processing unit (CPU). Die-package 106 may be thermally coupled to a heat spreader 104 by a thermal interface material (TIM) layer 110. The heat spreader 104 may be mechanically coupled to the die-package substrate 140 by sealant 124. The heat spreader 104 may be mechanically coupled to the package substrate 102 by sealant 122. Die-package 106 may include additional elements 130. Additional elements 130 may include passive or active elements including, but not limited to, die side capacitors.

Die-package 112 may include one or more dies, such as die 114. Die 114 may contain any passive or active elements. For instance, die 114 may include a fabric chip or a memory chip. Die 114 may be coupled to a die-package substrate 150 by die-package interconnects 152. Die-package interconnects 152 may be any suitable structures, including but not limited to a BGA, bumps, or posts. Die-package 112 may be thermally coupled to a heat spreader 104 by a TIM layer 116.

Die-packages 106 and/or 112 may each have dimensional variability due to the nature of their fabrication. Die-packages 106 and 112 may be the result of different fabrication processes and in some instance may be fabricated by different suppliers. This may lead to different tolerances and dimensional variability between die-packages that are ultimately to be assembled into a package assembly such as package assembly 100. The heat spreader 104 may define a finite height relative to the package substrate 102, into which the die-packages such as die-packages 106 and/or 112 will fit. Thus, design and fabrication of the heat spreader 104 may be performed to accommodate the thickest die-package dimension that results due to the dimensional variability present in the fabrication process. As such, in some instances, where a die-package is thinner due to the dimensional variability present in the fabrication process, the additional space between the thinner die-package and a heat spreader may be filled when thermally coupling the die-package to a heat spreader, such as heat spreader 104. This phenomenon can be seen, for example, by comparing FIGS. 1B and 1C.

FIG. 1B illustrates a blown-up view of the right side of package assembly 100 from FIG. 1A. In FIG. 1B, die-package 112 is shown as being relatively thick such that TIM layer 116 is relatively thin in comparison with the die-package 112 and TIM layer 116 of FIG. 1C. In contrast, in FIG. 1C die-package 112 is shown as being relatively thin such that TIM layer 116 is thicker to thermally couple die-package 112 to heat spreader 104. The variation seen in die-package 112 between FIG. 1B and FIG. 1C may be the result of fabrication tolerances such that a group of die-packages, such as die-package 112, fabricated by a supplier will have different final dimensions.

The variability in the die-package thickness and resulting variability in the thickness of the TIM layer may be problematic because the thermal resistance of the TIM layer 116 may increase as the thickness of the TIM layer 116 increases. As such, a thinner TIM layer, such as that shown in FIG. 1B, may more effectively transfer heat from die-package 112 to heat spreader 104. In addition to added thermal resistance due to additional thickness, the variability of the required thickness of the TIM layer limits the choice of materials. For instance, many pad type TIM layer materials may not be sufficiently compressible to accommodate the required dimensional variability. Additionally, some thermal grease materials may lack the thermal conductivity required, particularly where the dimensions require relatively thick TIM layers.

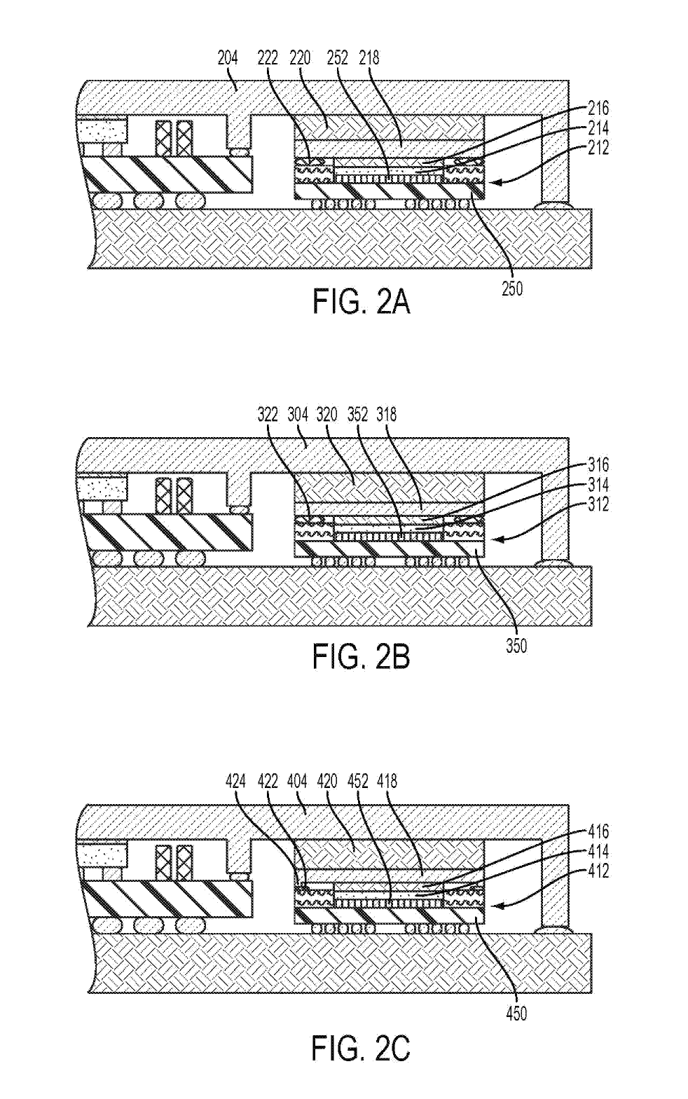

FIGS. 2A-F illustrate cross-section side views of a package assembly including various die-package heat spreaders, in accordance with some embodiments. While FIGS. 2A-F show particular arrangements of parts and die-packages the die-package heat spreader techniques shown in FIGS. 2A-F may be utilized in a variety of die-package configurations. FIGS. 2A-F are blown-up views of a die-package and the surrounding portion. It should be understood those portions of package assembly that are not shown may take on different configurations including for instance the configuration shown in FIGS. 1A-C.

FIG. 2A illustrates a portion of a package assembly that may include a die-package 212. Die-package 212 may include die 214. Die 214 may contain any passive or active elements. For instance, die 214 may include a fabric chip or a memory chip. Die 214 may be coupled to a die-package substrate 250 by die package interconnects 252. Die-package interconnects 252 may be any suitable structures, including but not limited to a BGA, bumps, or posts. Rather than being directly coupled to a package heat spreader 204, die-package 212 may be thermally coupled to a die-package heat spreader 218 by TIM layer 216. The die-package heat spreader 218 may be thermally coupled to the package heat spreader 204 by an additional TIM layer 220. The die-package heat spreader 218 may be mechanically coupled to the die-package 212 by sealant 222. While TIM layer 216 may also provide some level of mechanical coupling between die-package heat spreader 218 and die-package 212, its primary purpose is to provide a thermal pathway to conduct heat from die-package 212 to die-package heat spreader 218. Similarly, sealant 222 may provide some level of thermal coupling between die-package heat spreader 218 and die-package 212, but its primary purpose is to provide a structural connection between die-package 212 and die-package heat spreader 218.

By placing the die-package heat spreader 218 in close proximity to the die-package 212 it may be possible to provide better heat transfer from die-package 212 as compared to the configurations shown in FIGS. 1A-C. Die-package heat spreader 218 may also have a surface area larger than die 214. This may allow heat generated by die 214 to be transferred to the package heat spreader 204, by way of die-package heat spreader 218 over a larger area and thus more efficiently. This arrangement may allow heat to initially flow from the die 214 to the die-package heat spreader 218 in an efficient manner due to proximity of the die-package heat spreader 218 to the die 214. The increased surface area of die-package heat spreader 218 relative to the die 214, can decrease or eliminate the deleterious effects of variability in the TIM layer 220. The dimensions of the die-package 212 may still vary as discussed above with regard to FIG. 1, but the presence of the die-package heat spreader 218 allows heat to be transferred from die 214 to die-package heat spreader 218 with limited thermal resistance. The variability in thickness may be accounted for in TIM layer 220 at which point the heat may be transferred over a larger surface area defined by the size of the die-package heat spreader 218 and TIM layer 220.

FIGS. 2B-F show various configurations for incorporating a die-package heat spreader, such as die-package heat spreader 218, into a die-package as discussed below. In general, each of FIGS. 2B-F may achieve similar benefits to those discussed above relative to FIG. 2A.

FIG. 2B illustrates a portion of a package assembly, in accordance with some embodiments, that may include a die-package 312. Die-package 312 may include die 314. Die 314 may contain any passive or active elements. For instance, die 314 may include a fabric chip or a memory chip. Die 314 may be coupled to a die-package substrate 350 by die package interconnects 352. Die-package interconnects 352 may be any suitable structures, including but not limited to a BGA, bumps, or posts. Rather than being directly coupled to a package heat spreader 304, die-package 312 may be thermally coupled to a die-package heat spreader 318 by TIM layer 316. The die-package heat spreader 318 may be thermally coupled to the package heat spreader 304 by an additional TIM layer 320. The die-package heat spreader 318 may be mechanically coupled to the die-package 312 by sealant 322. Die-package heat spreader 318 may be a relatively thin plate when compared to die-package heat spreader 218 of FIG. 2A. This may be beneficial where additional flexibility is needed in the height of TIM layer 320 due to dimensional variability of the die-package 312.

FIG. 2C illustrates a portion of a package assembly, in accordance with some embodiments, that may include a die-package 412. Die-package 412 may include die 414. Die 414 may contain any passive or active elements. For instance, die 414 may include a fabric chip or a memory chip. Die 414 may be coupled to a die-package substrate 450 by die package interconnects 452. Die-package interconnects 452 may be any suitable structures, including but not limited to a BGA, bumps, or posts. Rather than being directly coupled to a package heat spreader 404, die-package 412 may be thermally coupled to a die-package heat spreader 418 by TIM layer 416. The die-package heat spreader 418 may be thermally coupled to the package heat spreader 404 by an additional TIM layer 420. The die-package heat spreader 418 may be mechanically coupled to the die-package 412 by sealant 422. Die-package heat spreader 418 may have legs 424 to facilitate the mechanical connection depending upon the configuration of the die-package 412.

FIG. 2D illustrates a portion of a package assembly, in accordance with some embodiments, that may include a die-package 512. Die-package 512 may include die 514. Die 514 may contain any passive or active elements. For instance, die 514 may include a fabric chip or a memory chip. Die 514 may be coupled to a die-package substrate 550 by die package interconnects 552. Die-package interconnects 552 may be any suitable structures, including but not limited to a BGA, bumps, or posts. Rather than being directly coupled to a package heat spreader 504, die-package 512 may be thermally coupled to a die-package heat spreader 518 by TIM layer 516. The die-package heat spreader 518 may be thermally coupled to the package heat spreader 504 by an additional TIM layer 520. The die-package heat spreader 518 may be mechanically coupled to the package substrate 502 by sealant 522. Die-package heat spreader 518 may have legs 524 to facilitate the mechanical connection depending upon the configuration of the die-package 512. This configuration may also result in additional heat transfer due to the larger surface area of the die-package heat spreader 518 (extending beyond the die-package 512, as discussed below regarding FIG. 2E) as well as due to potential heat transfer to the atmosphere provided by legs 524.

FIG. 2E illustrates a portion of a package assembly, in accordance with some embodiments, that may include a die-package 612. Die-package 612 may include die 614. Die 614 may contain any passive or active elements. For instance, die 614 may include a fabric chip or a memory chip. Die 614 may be coupled to a die-package substrate 650 by die package interconnects 652. Die-package interconnects 652 may be any suitable structures, including but not limited to a BGA, bumps, or posts. Rather than being directly coupled to a package heat spreader 604, die-package 612 may be thermally coupled to a die-package heat spreader 618 by TIM layer 616. The die-package heat spreader 618 may be thermally coupled to the package heat spreader 604 by an additional TIM layer 620. The die-package heat spreader 618 may be mechanically coupled to the die-package 612 by sealant 622. The arrangement of FIG. 2E is similar to that of FIGS. 2A-B, except that the die-package heat spreader 618 has a larger area than the die-package 612 such that it extends beyond the die-package 612 in a horizontal direction. The additional surface area of die-package heat spreader 618 may accentuate the benefits discussed above by providing a larger thermal pathway between the die-package heat spreader 618 and the package heat spreader 604.

FIG. 2F illustrates a portion of a package assembly, in accordance with some embodiments, that may include a die-package 712. Die-package 712 may include die 714. Die 714 may contain any passive or active elements. For instance, die 714 may include a fabric chip or a memory chip. Die 714 may be coupled to a die-package substrate 750 by die package interconnects 752. Die-package interconnects 752 may be any suitable structures, including but not limited to a BGA, bumps, or posts. A die-package heat spreader 718 and a TIM layer 716 may be incorporated as integral parts of the die-package 712. For instance, the TIM layer 716 and the die-package heat spreader 718 may be incorporated into the die-package 712 during fabrication. The die-package 712 may include a mold compound 722 that retains the die-package heat spreader 718. The mold compound 722 may partially encapsulate the die-package heat spreader 718 such that only the upper surface of the die-package heat spreader 718 is exposed. The die-package heat spreader 718 may be thermally coupled to a package heat spreader 704 by a TIM layer 718.

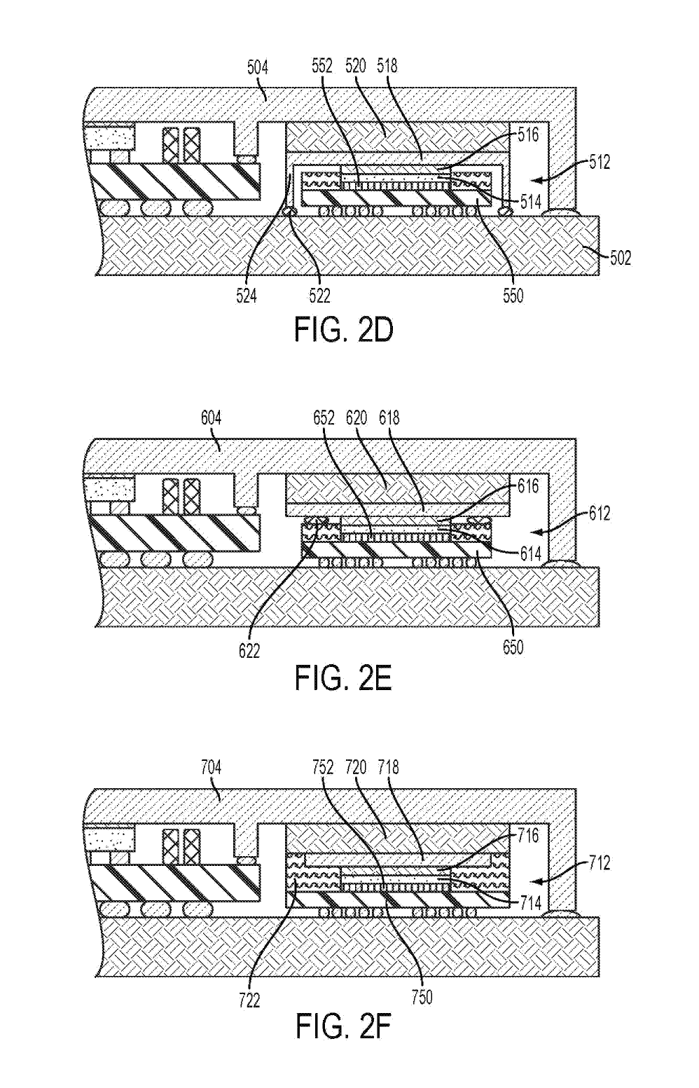

FIG. 3 schematically illustrates a flow diagram of a method 800 of fabricating a package assembly (e.g., package assemblies according to FIGS. 1-2), in accordance with some embodiments.

At 802 the method 800 may include coupling a first die-package (e.g., die-package 106 of FIG. 1) with a package substrate. Any suitable technique may be used to attach the die-package to the package substrate consistent with the package assemblies discussed relative to FIGS. 1-2 above, as well any other suitable techniques for additional package assemblies not specifically discussed herein.

At 804 the method 800 may include coupling a second die-package (e.g. die-packages 112-712 of FIGS. 1-2) with a package substrate. Any suitable techniques may be used to couple the second die-package with the package substrate

At 806 the method 800 may include thermally coupling a first die-package heat spreader (e.g., die-package heat spreaders 218-718 of FIGS. 2A-F) with the second die-package (e.g., die-packages 112-712 of FIGS. 1-2). Any suitable techniques may be used to thermally couple the first die-package heat spreader with the second die-package. For instance, this operation may include depositing or placing a TIM layer (e.g., TIM layers 216-716 of FIGS. 2A-F) onto a die (e.g., dies 214-714 of FIGS. 2A-F) and then placing the die-package heat spreader onto the TIM layer. As discussed above relative to FIG. 2F, operation 806 may be performed as part of the fabrication of a die-package such that the first die-package heat spreader may be thermally coupled with the die-package (or incorporated as an integral portion of the die-package as discussed regarding FIG. 2F) prior to coupling the second die-package to the package substrate. Although discussed with regard to FIG. 2F, it is possible in any of the configurations to thermally couple the die-package heat spreader with the second die-package prior to coupling the second die-package to the package substrate.

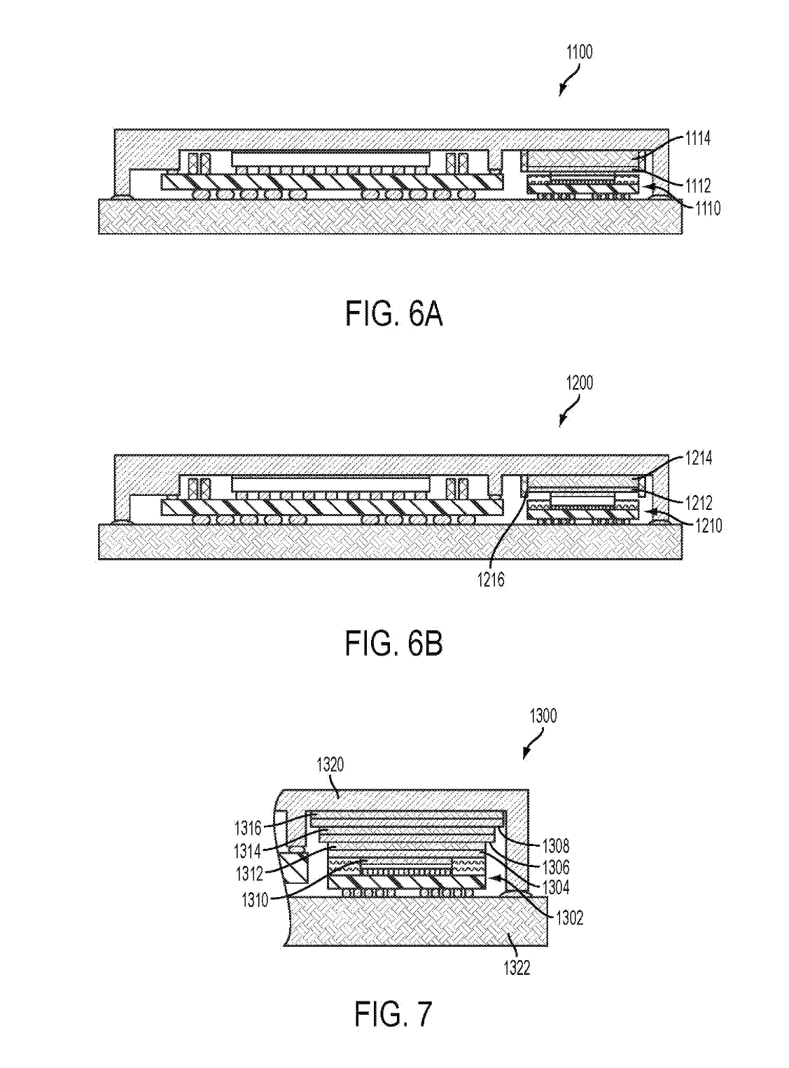

At 808 the method 800 may include thermally coupling a second die-package heat spreader (e.g., die-package heat spreaders 1306 and/or 1308 of FIG. 7) with the first die-package heat spreader (e.g., die-package heat spreader 1304 of FIG. 7). This operation is optional and results in an additional die-package heat spreader as shown, for example, in the arrangement of FIG. 7. Any suitable techniques may be used to thermally couple the second die-package heat spreader with the first die-package heat spreader. For instance, this operation may include depositing or placing a TIM layer (e.g., TIM layers 1312 and/or 1314 of FIG. 7) onto the first die-package heat spreader and then placing the second die-package heat spreader onto the TIM layer.

At 810 the method may include thermally coupling a package heat spreader (e.g., 104-704 and 1320 of FIGS. 1-2 and 7) with the first die-package (e.g., die-package 106 of FIG. 1, also seen but not labeled in FIGS. 2A-F) and one of the die-package heat spreaders (e.g., 218-718 and 1306 and/or 1308 of FIGS. 1-2 and 7). Any suitable techniques may be used to thermally couple the package heat spreader with the first die-package and the one of the die-package heat spreaders. For instance, this operation may include depositing or placing a TIM layer onto both the first die-package and the one of the die-package heat spreaders and subsequently placing the package heat spreader onto the TIM layers.

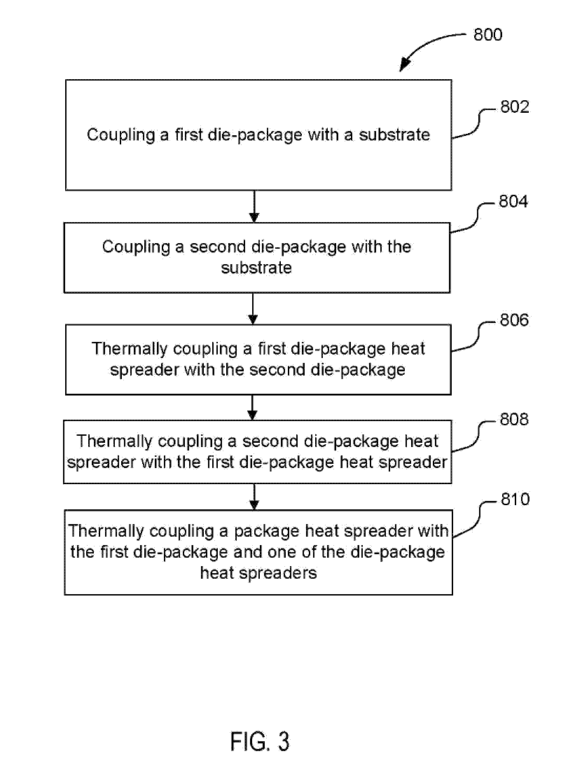

FIGS. 4A-C illustrate cross-section side views of a heat spreader 900 and package assembly 920 including the heat spreader 900, in accordance with some embodiments.

FIG. 4A illustrates a heat spreader 900, in accordance with some embodiments. The heat spreader 900 may include a package heat spreading portion 902. In general the package heat spreading portion 902 may represent the outermost portion of the heat spreader 900 from which the heat spreader 900 dissipates heat to the surrounding environment. The package heat spreading portion 902 may include a plurality of heat spreading regions, such as heat spreading regions 906 and 904. The heat spreading regions may be configured to accommodate die-packages when the heat spreader 900 is thermally coupled to underlying die-packages. The package heat spreading regions may be defined by projecting portions, such as projecting portion 912. The heat spreader may include legs, such as leg 914. The legs may project downward from the package heat spreading portion 902 and may facilitate the mechanical coupling of the heat spreader 900 to an underlying package substrate.

The heat spreader 900 may include one or more die-package heat spreading portions, such as die-package heat spreading portion 908. Although only one die-package heat spreading portion is shown any number of die-package heat spreading portions may be included in a variety of configurations. For instance, it is possible to include a die-package heat spreading portion in each of heat spreading regions or to include a plurality of heat spreading regions some with and others without die-package heat spreading portions. The die-package heat spreading portion 908 may be attached to the package heat spreading portion 902 by rails 910. The die-package heat spreading portion 908 and the rails 910 may be configured such that the die-package heat spreading portion 908 may move relative to the package heat spreading portion 902. For instance, the die-package heat spreading portion 908 may be connected to the rails 910 in a manner that allows the die-package heat spreading portion 908 to slide vertically along the rails. Alternatively, it may also be possible to form rails 910 of a compliant material such that they will deflect when a force is exerted vertically on the die-package heat spreading portion 908. In this instance the movement of the die-package heat spreading portion 908 relative to the package heat spreading region 902 is achieved by the deflection of the rails as opposed to the movement of the die-package heat spreading portion 908 along the rails 910.

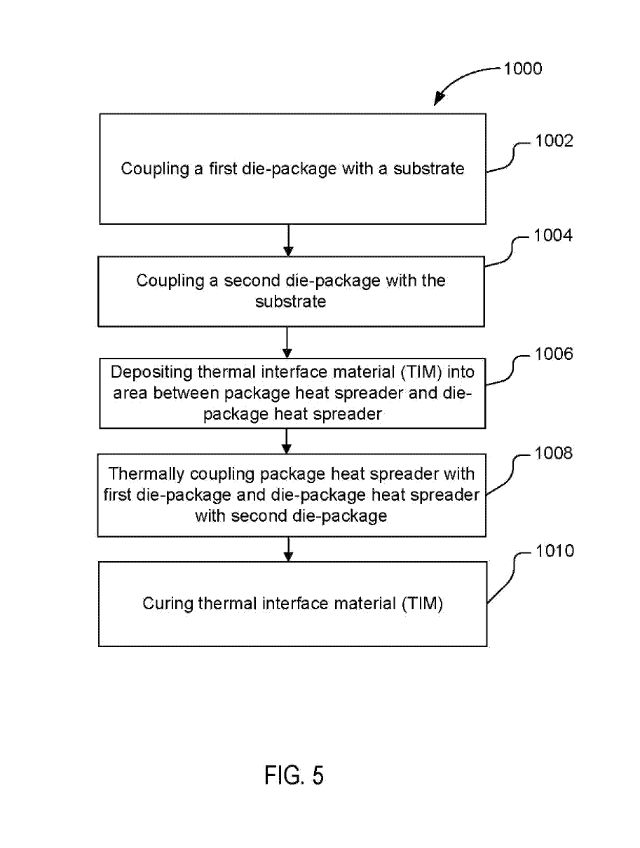

FIG. 4B illustrates the heat spreader 900 during an intermediate operation of the installation process. As seen in FIG. 4B a TIM material 916 may be added in the area between the die-package heat spreading portion 908 and the package heat spreading portion 902. The TIM material may be a thermal grease material or other generally flowable material that exhibits satisfactory thermal characteristics. By using a thermal grease material or other similar materials the die-package heat spreading portion 908 may be movable during the fabrication process to allow it to assume a vertical position based on the height of an underlying die-package. As such, the vertical position of the die-package heat spreading portion 908 may be variable to account for dimensional variability in the underlying die-package. This feature is discussed in more detail with reference to FIGS. 6A-B. The TIM material 916 may be cured as part of the fabrication process. This may result in the final position of the die-package heat spreading portion 908 be fixed during the curing operation.

FIG. 4C illustrates the heat spreader 900 installed as part of a package assembly 920. The heat spreader 900 may be mechanically coupled to the package substrate 930 as well as one or more underlying packages 906, 918 with a sealant 922, 924. As discussed previously, TIM layers may be deposited onto underlying die-packages to thermally couple the die-packages to the heat spreader 900. The ability of the die-package heat spreading portion 908 to move relative to the package heat spreading portion 902 can be seen in FIG. 4C. In this instance, the underlying die-package 918 has a height such that as the heat spreader 900 is installed the die-package heat spreading portion 908 moves vertically along rails 910 to accommodate the vertical dimensions of the underlying die-package 918. This is visible in the change in position of die-package heat spreading portion 908 from FIGS. 4A-B to 4C. The substrate and underlying die-package are similar to those discussed in reference to FIGS. 1A-C and may take on a variety of configurations.

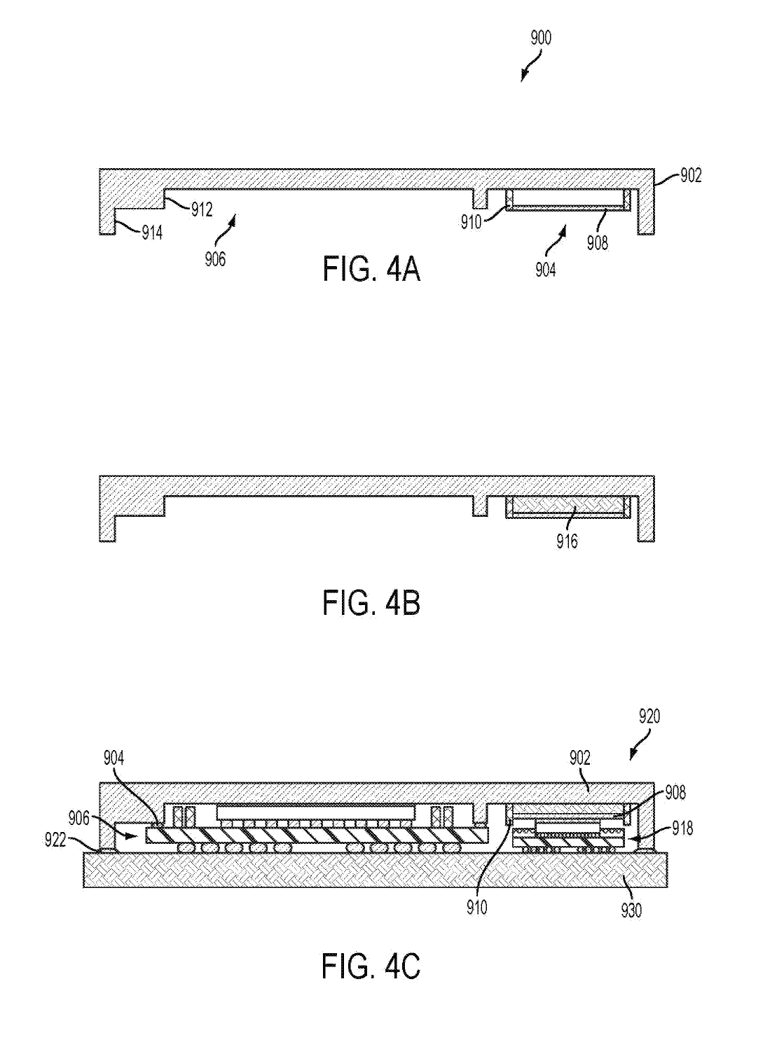

FIG. 5 schematically illustrates a flow diagram of a method 1000 of fabricating a package assembly (e.g., package assembly 920 according to FIG. 4C), in accordance with some embodiments.

At 1002 the method 1000 may include coupling a first die-package with a package substrate. Any suitable technique may be used to attach the die-package to the package substrate.

At 1004 the method 1000 may include coupling a second die-package with the package substrate. Any suitable techniques may be used to couple the second die-package with the package substrate.

At 1006 the method 1000 may include depositing TIM material into an area between a package heat spreader (e.g., package heat spreading portion 902 of FIGS. 4A-C) and a die-package heat spreader (e.g., die-package heat spreading portion 908 of FIGS. 4A-C). Any suitable techniques and materials may be used in this operation. In some instances the TIM material may be a thermal grease material.

At 1008 the method 1000 may include thermally coupling a package heat spreader (e.g., package heat spreading portion 902 of FIGS. 4A-C) with a first die-package and thermally coupling a die-package heat spreader (e.g., die-package heat spreading portion 908 of FIGS. 4A-C) with a second die-package. Any suitable techniques may be used to perform this operation. For instance, this operation may include depositing or placing a TIM layer onto the first die-package and the second die-package and then placing the heat spreader including both the package heat spreader and the die-package heat spreader onto the TIM layers.

At 1010 the method 1000 may include curing the TIM material (e.g., TIM material 916 in FIG. 4B). Any suitable techniques may be used to complete this operation. In some instances, this operation may include applying heat or ultra-violet (UV) radiation to the package assembly. As discussed previously, this operation may result in the position of the die-package heat spreader becoming fixed relative to the package heat spreader due to changes in the physical characteristics of the TIM material as a result of curing.

FIGS. 6A-B illustrate cross-section side views of package assemblies 1100 and 1200, similar to the package assembly 920 of FIG. 4C, showing different positions of a die-package heat spreading portion due to dimensional variability of an underlying die-package.

FIG. 6A shows a package assembly 1100 in which an underlying die-package 1110 is relatively thin due to variability in the fabrication process. This may result in a die-package heat spreading portion 1112 that does not move or moves only minimally when being installed. As discussed previously, the die-package heat spreading portion 1112 may be able to slide along rails to accommodate varying heights of the underlying die-package 1110. In this instance, where the height of the underlying die-package 1110 is on the smaller end of the expected range of heights, the die-package heat spreading portion 1112 may not need to move or may move only minimally upon installation and little if any of the TIM material 1114 may be displaced.

FIG. 6B shows a package assembly 1200 in which an underlying die-package 1210 is relatively thick due to variability in the fabrication process. In this instance, the die-package heat spreading portion 1212 may slide vertically along the rails 1216 to compensate for the larger height of the underlying die-package 1212. Here, some amount of the TIM material 1214 may be displaced (forced out of the area between the die-package heat spreading portion 1112 and package heat spreading portion) by the movement of the die-package heat spreading portion 1112. By allowing the die-package heat spreading portion 1112 to move during the installation process the heat spreader may accommodate a substantial variation in height of the underlying die-package 1210.

FIG. 7 illustrates a cross-section side view of a portion of a package assembly including multiple die-package heat spreaders, in accordance with some embodiments. FIG. 7 shows a portion of package assembly 1300. The package assembly 1300 may include a die-package 1302. The die-package 1302 may be coupled with a package substrate 1322 as discussed previously. The package assembly 1300 may include a package heat spreader 1320. The package assembly 1300 may include one or more die-package heat spreaders, such as die-package heat spreaders 1304, 1306, and 1308. The die-package heat spreaders 1304, 1306, and 1308 may be thermally coupled to adjacent die-packages or heat spreaders by TIM layers, such as TIM layers 1310, 1312, 1314, and 1316. For instance, die-package heat spreader 1304 may be thermally coupled to the die-package 1302 by TIM layer 1310. The surface area of each die-package heat spreader may be larger than that of an underlying die or die-package heat spreader. As discussed previously, larger surface areas may provide better flow of heat away from heat generating elements, such as a die incorporated in die-package 1302, to a package heat spreader, such as package heat spreader 1320, to dissipate the heat to the surrounding atmosphere. Utilizing numerous die-package heat spreaders may prevent any individual TIM layer from becoming overly thick and thus creating challenges due to increased thermal resistance. While three die-package heat spreaders 1304, 1306, and 1308 are shown any number of die-package heat spreaders may be used.

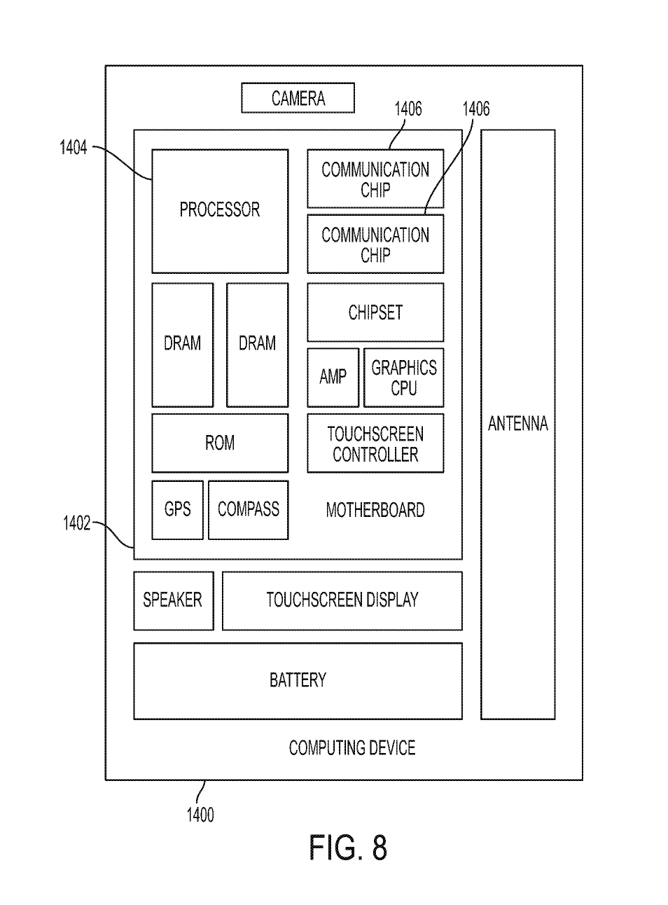

Embodiments of the present disclosure may be implemented into a system using any suitable hardware and/or software to configure as desired. FIG. 8 schematically illustrates a computing device 1400 that includes an IC package assembly (e.g., one or more of package assemblies according to any of FIG. 2, 4, 6, or 7) as described herein, in accordance with some embodiments. The computing device 1400 may include housing to house a board such as motherboard 1402. Motherboard 1402 may include a number of components, including but not limited to processor 1404 and at least one communication chip 1406. Processor 1404 may be physically and electrically coupled to motherboard 1402. In some implementations, the at least one communication chip 1406 may also be physically and electrically coupled to motherboard 1402. In further implementations, communication chip 1406 may be part of processor 1404.

Depending on its applications, computing device 1400 may include other components that may or may not be physically and electrically coupled to motherboard 1402. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

Communication chip 1406 may enable wireless communications for the transfer of data to and from computing device 1400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 1406 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. Communication chip 1406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1406 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. Communication chip 1406 may operate in accordance with other wireless protocols in other embodiments.

Computing device 1400 may include a plurality of communication chips 1406. For instance, a first communication chip 1406 may be dedicated to shorter range wireless communications such as Wi-Fi and Bluetooth, and a second communication chip 1406 may be dedicated to longer range wireless communications such as GPS, EDGE, GPRS, CDMA, WiMAX, LTE, Ev-DO, and others.

Processor 1404 of computing device 1400 may be packaged in an IC assembly (e.g., one or more of package assemblies according to any of FIG. 2, 4, 6, or 7) as described herein. For example, processor 1404 may correspond with die 108. The package assembly (e.g., one or more of package assemblies according to any of FIG. 2, 4, 6, or 7) and motherboard 1402 may be coupled together using package-level interconnects such as BGA balls. The term “processor” may refer to any device or portion of a device that processes electronic data from registers and/or memory to transform that electronic data into other electronic data that may be stored in registers and/or memory.

Communication chip 1406 may also include a die that may be packaged in an IC assembly (e.g., one or more of package assemblies according to any of FIG. 2, 4, 6, or 7) as described herein. In further implementations, another component (e.g., memory device or other integrated circuit device) housed within computing device 1400 may include a die that may be packaged in an IC assembly (e.g., one or more of package assemblies according to any of FIG. 2, 4, 6, or 7) as described herein.

In various implementations, computing device 1400 may be a laptop, a netbook, a notebook, an Ultrabook™, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1400 may be any other electronic device that processes data.

Various operations are described as multiple discrete operations in turn, in a manner that is most helpful in understanding the claimed subject matter. However, the order of description should not be construed as to imply that these operations are necessarily order dependent.

### Examples

Some non-limiting examples are provided below.

Example 1 includes a package assembly comprising: a package substrate; a first die-package coupled to the package substrate; a second die-package coupled to the package substrate; a die-package heat spreader thermally coupled to the second die-package; and a package heat spreader thermally coupled to the first die-package and the die-package heat spreader.

Example 2 includes the package assembly of example 1, wherein: the die-package heat spreader is a first die-package heat spreader and the package assembly includes a second die-package heat spreader located between the first die-package heat spreader and the package heat spreader.

Example 3 includes package assembly of example 1, wherein: the die-package heat spreader is an integral part of the second die-package.

Example 4 includes package assembly of example 1, wherein: the die-package heat spreader is mechanically coupled to the second die-package with a sealant.

Example 5 includes the package assembly of example 1, wherein: the die-package heat spreader is mechanically coupled to the package substrate with a sealant.

Example 6 includes the package assembly of example 1, wherein: the die-package heat spreader is attached to the package heat spreader by rails.

Example 7 includes the package assembly of any of examples 1-6, wherein: a first side of the package heat spreader is thermally coupled to the first die-package and the die-package heat spreader and a second opposite side of the package heat spreader is substantially flat.

Example 8 includes package assembly of any of examples 1-6, wherein: the package heat spreader is mechanically coupled to the package substrate and to the first die-package with a sealant.

Example 9 includes a heat spreader comprising: a package heat spreading portion including: a first heat spreading region for accommodating a first die-package; and a second heat spreading region for accommodating a second die-package; a die-package heat spreading portion attached to the package heat spreading portion by rails protruding from the package heat spreading portion.

Example 10 includes the heat spreader of example 9, wherein: the die-package heat spreading portion is movable along the rails relative to the package heat spreading portion.

Example 11 includes the heat spreader of example 9 or 10, wherein: the die-package heat spreading portion is attached to a first side of the package heat spreading portion, and a second opposite side of the package heat spreading portion is substantially flat.

Example 12 includes the heat spreader of example 9 or 10, wherein: the package heat spreading portion is a contiguous, unitary structure.

Example 13 includes the heat spreader of example 9 or 10, comprising a plurality of portions protruding from the package heat spreading portion, wherein: the plurality of portions protruding from the package heat spreading portion define the first heat spreading region and the second heat spreading region.

Example 14 includes a method of fabricating a package assembly, the method comprising: coupling a first die-package with a package substrate; coupling a second die-package with the package substrate; and thermally coupling a package heat spreader with the first die-package and a die-package heat spreader, wherein the die-package heat spreader is configured for thermal coupling with the second die-package.

Example 15 includes the method of example 14, comprising: thermally coupling the die-package heat spreader with the second die-package prior to thermally coupling the package heat spreader with the first die-package and the die-package heat spreader.

Example 16 includes the method of example 15, wherein: the die-package heat spreader is a first die-package heat spreader, the method further comprising: thermally coupling a second die-package heat spreader between the first die-package heat spreader and the package heat spreader

Example 17 includes method of example 14, wherein: the second die-package includes the die-package heat spreader.

Example 18 includes the method of any of examples 14-17, wherein: thermally coupling the package heat spreader with the first die-package and the die-package heat spreader further includes coupling the die-package heat spreader with the second die-package.

Example 19 includes the method of any of examples 14-17, comprising: mechanically coupling the package heat spreader with the substrate and the first die-package.

Example 20 includes a computing device comprising: a circuit board; and a package assembly coupled with the circuit board, the package assembly including: a package substrate having a first side and a second side disposed opposite to the first side, the first side being coupled with the circuit board, a first die-package coupled to the second side of the package substrate, a second die-package coupled to the second side of the package substrate, a die-package heat spreader thermally coupled to the second die-package, and a package heat spreader thermally coupled to the first die-package and the die-package heat spreader.

Example 21 includes the computing device of example 20, wherein: the first die-package includes a central processing unit (CPU) and the second die-package includes a memory die.

Example 22 includes the computing device of example 20, wherein: the die-package heat spreader is an integral part of the second die-package.

Example 23 includes the computing device of any of examples 20-22, wherein: the die-package heat spreader is a first die-package heat spreader and the package assembly includes a second die-package heat spreader located between the first die-package heat spreader and the package heat spreader.

Example 24 includes the computing device of any of examples 20-22, wherein: the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

What is claimed is:

1. A package assembly comprising:
a package substrate;
a first die-package coupled to the package substrate;
a second die-package coupled to the package substrate;
a die-package heat spreader thermally coupled to the second die-package; and
a package heat spreader thermally coupled to the first die-package and the die-package heat spreader.

2. The package assembly of claim 1, wherein:
the die-package heat spreader is a first die-package heat spreader and the package assembly includes a second die-package heat spreader located between the first die-package heat spreader and the package heat spreader.

3. The package assembly of claim 1, wherein:
a first side of the package heat spreader is thermally coupled to the first die-package and the die-package heat spreader and a second opposite side of the package heat spreader is substantially flat.

4. The package assembly of claim 1, wherein:
the die-package heat spreader is an integral part of the second die-package.

5. The package assembly of claim 1, wherein:
the package heat spreader is mechanically coupled to the package substrate and to the first die-package with a sealant.

6. The package assembly of claim 1, wherein:
the die-package heat spreader is mechanically coupled to the second die-package with a sealant.

7. The package assembly of claim 1, wherein:
the die-package heat spreader is mechanically coupled to the package substrate with a sealant.

8. The package assembly of claim 1, wherein:
the die-package heat spreader is attached to the package heat spreader by rails.

9. A heat spreader comprising:
a package heat spreading portion including:
a first heat spreading region to accommodate a first die-package; and
a second heat spreading region to accommodate a second die-package; and
a die-package heat spreading portion attached to the package heat spreading portion by rails protruding from the package heat spreading portion.

10. The heat spreader of claim 9, wherein:
the package heat spreading portion is a contiguous, unitary structure.

11. The heat spreader of claim 9, wherein:
the die-package heat spreading portion is movable along the rails relative to the package heat spreading portion.

12. The heat spreader of claim 9, wherein:
the die-package heat spreading portion is attached to a first side of the package heat spreading portion, and a second opposite side of the package heat spreading portion is substantially flat.

13. The heat spreader of claim 9, comprising a plurality of portions protruding from the package heat spreading portion, wherein:
the plurality of portions protruding from the package heat spreading portion define the first heat spreading region and the second heat spreading region.

14. A method of fabricating a package assembly, the method comprising:
coupling a first die-package with a package substrate;
coupling a second die-package with the package substrate; and
thermally coupling a package heat spreader with the first die-package and a die-package heat spreader, wherein the die-package heat spreader is configured for thermal coupling with the second die-package.

15. The method of claim 14, comprising:
thermally coupling the die-package heat spreader with the second die-package prior to thermally coupling the package heat spreader with the first die-package and the die-package heat spreader.

16. The method of claim 15, wherein:
the die-package heat spreader is a first die-package heat spreader, the method further comprising:
thermally coupling a second die-package heat spreader between the first die-package heat spreader and the package heat spreader.

17. The method of claim 14, wherein:
thermally coupling the package heat spreader with the first die-package and the die-package heat spreader further includes coupling the die-package heat spreader with the second die-package.

18. The method of claim 14, wherein:
the second die-package includes the die-package heat spreader.

19. The method of claim 14, comprising:
mechanically coupling the package heat spreader with the substrate and the first die-package.

20. A computing device comprising:
a circuit board; and
a package assembly coupled with the circuit board, the package assembly including:
a package substrate having a first side and a second side disposed opposite to the first side, the first side being coupled with the circuit board,
a first die-package coupled to the second side of the package substrate,
a second die-package coupled to the second side of the package substrate,
a die-package heat spreader thermally coupled to the second die-package, and
a package heat spreader thermally coupled to the first die-package and the die-package heat spreader.

21. The computing device of claim 20, wherein:
the first die-package includes a central processing unit (CPU) and the second die-package includes a memory die.

22. The computing device of claim 20, wherein:
the die-package heat spreader is a first die-package heat spreader and the package assembly includes a second die-package heat spreader located between the first die-package heat spreader and the package heat spreader.

23. The computing device of claim 20, wherein:
the die-package heat spreader is an integral part of the second die-package.

24. The computing device of any of claims 20, wherein:
the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.
